(19) United States
(12) Patent Application Publication
(10) Pub. No.: US 2024/0395836 A1
(43) Pub. Date: Nov. 28, 2024

(54) SENSING DEVICE

(71) Applicant: InnoLux Corporation, Miao-Li County (TW)

(72) Inventors: Yu-Tsung LIU, Miao-Li County (TW); I-An YAO, Miao-Li County (TW)

(21) Appl. No.: 18/644,445

(22) Filed: Apr. 24, 2024

(30) Foreign Application Priority Data
May 24, 2023 (CN) 202310590720.7

(51) Int. Cl. H01L 27/146

(52) U.S. Cl. CPC H01L 27/14612; H01L 27/14629; H01L 27/14636

(57) ABSTRACT

A sensing device includes: a substrate, a circuit layer and a plurality of sensing units. The circuit layer is disposed on the substrate, and includes a plurality of driving circuits. The sensing unit is disposed on the circuit layer, and includes a supporting part and a sensing part. The supporting part is electrically connected to one of the driving circuits. The sensing part is electrically connected to the supporting part, and is separated from the circuit layer by a cavity through the supporting part. In a normal direction of the substrate, at least part of the supporting part overlaps with the sensing part.

### CROSS-REFERENCE TO RELATED APPLICATIONS

This application claims the benefits of the Chinese Patent Application Serial Number 202310590720.7, filed on May 24, 2023, the subject matter of which is incorporated herein by reference.

### BACKGROUND

### Field of the Disclosure

The present disclosure relates to a sensing device and, more particularly, to the component arrangement layout technology of a sensing device.

### Description of Related Art

The sensing capability of current sensing devices, such as sensing devices with light sensor arrays, is usually related to fill factor and thermal insulation capability, wherein the fill factor is, for example, related to the pixel sensing area and the pixel area ratio, and the thermal insulation capability is, for example, related to the cavity structure and the length of the support member. However, the sensing area and the support member of the sensing device in prior art are usually disposed on the same plane, which often influence and interfere with each other in design, thereby making the design difficult and also resulting in insufficient sensing capability of the sensing device.

Therefore, it is desired to provide an improved sensing device to alleviate and/or obviate the above problems.

### SUMMARY

The present disclosure provides a sensing device, which comprises: a substrate; a circuit layer disposed on the substrate, and provided with a plurality of driving circuits; and a plurality of sensing units disposed on the circuit layer, each sensing unit including: a supporting part electrically connected to one of the driving circuits; and a sensing part electrically connected to the supporting part, and separated from the circuit layer by a first cavity through the supporting part, wherein at least part of the supporting part overlaps with the sensing part in a normal direction of the substrate.

Other novel features of the disclosure will become more apparent from the following detailed description when taken in conjunction with the accompanying drawings.

### BRIEF DESCRIPTION OF DRAWINGS

FIG. 1 is a schematic diagram of a sensing device according to an embodiment of the present disclosure;

FIG. 2 is a schematic diagram of a driving circuit and a sensing unit according to the first embodiment of the present disclosure;

FIG. 3 is a cross-sectional view of the driving circuit and sensing unit of FIG. 2 taken along line A-A′;

FIG. 4 is a schematic diagram of a driving circuit and a sensing unit according to the second embodiment of the present disclosure; and

FIG. 5 is a schematic diagram of a driving circuit and a sensing unit according to the third embodiment of the present disclosure.

### DETAILED DESCRIPTION OF EMBODIMENT

Reference will now be made in detail to exemplary embodiments of the present application, examples of which are illustrated in the accompanying drawings. Wherever possible, the same reference numerals are used in the drawings and description to refer to the same or like parts.

Throughout the specification and the appended claims, certain terms may be used to refer to specific components. Those skilled in the art will understand that electronic device manufacturers may refer to the same components by different names. The present application does not intend to distinguish between components that have the same function but have different names. In the following description and claims, words such as “containing” and “comprising” are open-ended words, and should be interpreted as meaning “including but not limited to”.

Directional terms mentioned in the specification, such as “up”, “down”, “front”, “rear”, “left”, “right”, etc., only refer to the directions of the drawings. Accordingly, the directional term used is illustrative, not limiting, of the present disclosure. In the drawings, various figures illustrate the general characteristics of methods, structures and/or materials used in particular embodiments. However, these drawings should not be construed to define or limit the scope or nature encompassed by these embodiments. For example, the relative sizes, thicknesses and positions of various layers, regions and/or structures may be reduced or enlarged for clarity.

One structure (or layer, component, substrate) described in the present disclosure is disposed on/above another structure (or layer, component, substrate), which can mean that the two structures are adjacent and directly connected, or can refer to two structures that are adjacent rather than directly connected. Indirect connection means that there is at least one intermediate structure (or intermediate layer, intermediate component, intermediate substrate, intermediate space) between the two structures, the lower surface of one structure is adjacent to or directly connected to the upper surface of the intermediate structure, and the upper surface of the other structure is adjacent to or directly connected to the lower surface of the intermediate structure. The intermediate structure may be a single-layer or multi-layer physical structure or a non-physical structure, which is not limited. In the present disclosure, when a certain structure is arranged “on” other structures, it may mean that a certain structure is “directly” on other structures, or it means that a certain structure is “indirectly” on other structures; that is, at least one structure is sandwiched, in between a certain structure and other structures.

The terms, such as “about”, “substantially”, or “approximately”, are generally interpreted as within 20% of a given value or range, or as within 10%, 5%, 3%, 2%, 1%, or 0.5% of a given value or range.

Furthermore, any two values or directions used for comparison may have certain errors. If the first value is equal to the second value, it implies that there may be an error of about 10% between the first value and the second value. If the first direction is perpendicular or “approximately” perpendicular to the second direction, the angle between the first direction and the second direction may be between 80 degrees and 100 degrees. If the first direction is parallel or “substantially” parallel to the second direction, the angle between the first direction and the second direction may be between 0 degrees and 10 degrees.

In the specification and claims, unless otherwise specified, ordinal numbers, such as “first” and “second”, used herein are intended to distinguish elements rather than disclose explicitly or implicitly that names of the elements bear the wording of the ordinal numbers. The ordinal numbers do not imply what order an element and another element are in terms of space, time or steps of a manufacturing method. Thus, what is referred to as a “first element” in the specification may be referred to as a “second element” in the claims.

In the present disclosure, the terms “a given range is from a first value to a second value” or “a given range is within a range from the first value to the second value” means that the given range includes the first value, the second value and other values between the first value and the second value.

It should be understood that, according to the embodiments of the present disclosure, an optical microscope (OM), a scanning electron microscope (SEM), a film thickness profiler (α-step), an ellipse thickness gauge or other suitable measurement means may be used to measure the depth, thickness, width or height of each component, or the spacing or distance between components. According to some embodiments, a scanning electron microscope may be used to obtain a cross-sectional structural image including the components to be measured, and measure the depth, thickness, width or height of each component, or the spacing or distance between components.

In this specification, the electronic device may include a display device, a backlight device, an antenna device, a sensing device or a tiled device, but it is not limited thereto. The electronic device may be a bendable or flexible electronic device. The display device may be a non-self-luminous display device or a self-luminous display device. The antenna device may be a liquid crystal type antenna device or a non-liquid crystal type antenna device, and the sensing device may be a sensing device that senses capacitance, light, heat energy or ultrasonic waves, but it is not limited thereto. The electronic components may include passive components and active components, such as capacitors, resistors, inductors, diodes, transistors or semiconductor wafers. The diodes may include light emitting diodes or photodiodes. The light emitting diode may include, for example, an organic light emitting diode (OLED), a sub-millimeter light emitting diode (mini LED), a micro light emitting diode (micro LED) or a quantum dot light emitting diode (quantum dot LED), but it is not limited thereto. The tiled device may be, for example, a display tiled device or an antenna tiled device, but it is not limited thereto. It should be noted that the electronic device may be any combination of the above, but it is not limited thereto. In the following description, the sensing device will be used as an electronic device or a tiled device to illustrate the present disclosure, but the present disclosure is not limited thereto.

It is noted that the following are exemplary embodiments of the present disclosure, but the present disclosure is not limited thereto, while a feature of some embodiments can be applied to other embodiments through suitable modification, substitution, combination, or separation. In addition, the present disclosure can be combined with other known structures to form further embodiments.

Unless otherwise defined, all terms (including technical and scientific terms) used herein have the same meaning as commonly understood by those skilled in the art related to the present disclosure. It can be understood that these terms, such as those defined in commonly used dictionaries, should be interpreted as having meaning consistent with the relevant technology and the background or context of the present disclosure, and should not be interpreted in an idealized or excessively formal way. Unless there is a special definition in the embodiment of the present disclosure.

In addition, the term “adjacent” in the specification and claims is used to describe mutual proximity, and does not necessarily mean mutual contact.

In addition, descriptions such as “when . . . ” or “while” in the present disclosure refer to aspects such as “at the moment, before or after”, but not limited to situations that occur at the same time. Similar descriptions such as “disposed on” in the present disclosure indicate the corresponding positional relationship between two components, but not limited to whether there is contact between the two components, unless otherwise specified. Furthermore, when multiple effects are provided in the present disclosure, if the word “or” is used between the effects, it means that the effects may exist independently, but it does not exclude that multiple effects may exist at the same time.

In addition, the terms such as “electrically connected” or “coupled” in the specification and claims not only refer to a direct electrical connection with another component, but also refer to an indirect electrical connection with another component. The electrical connection includes direct electrical connection, indirect electrical connection, or communication between two components through wireless signals.

For convenience of explanation, a sensing device 1 is taken as an example to describe the sensing device in the following, but the present disclosure is not limited thereto.

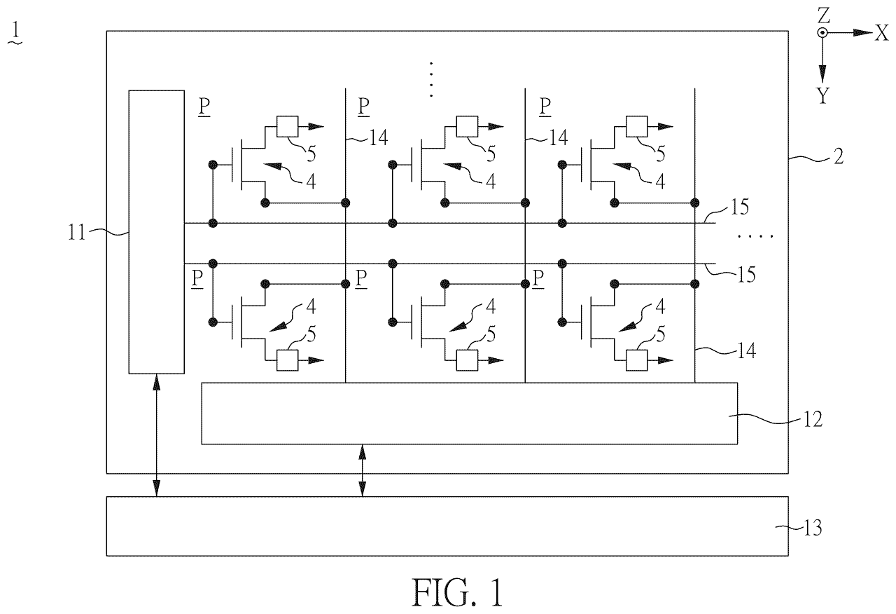

Please refer to FIG. 1, which is a schematic diagram of a sensing device 1 according to an embodiment of the present disclosure.

As shown in FIG. 1, the sensing device 1 may include a substrate 2 and a plurality of pixels P. The pixels P may be disposed on the substrate 2, and may be arranged, for example, in an array, but it is not limited thereto. Each pixel P may include at least one driving circuit 4 and at least one sensing unit 5, and the driving circuit 4 may be electrically connected to the sensing unit 5. Each driving circuit 4 may be electrically connected to at least one signal reader 12 through a reading line 14, and may be electrically connected to at least one scan driver 11 through a scan line 15. The scan driver 11 and the signal reader 12 may be electrically connected to a processing chip 13.

In one embodiment, the sensing unit 5 may include a resistor, for example, but it is not limited thereto. The driving circuit 4 may be, for example, a pixel switch, but it is not limited thereto. The signal reader 12 may be, for example, a data driver, but it is not limited thereto. The scan driver 11 may transmit signals to the driving circuit 4 through the scan lines 15 to cause the driving circuit 4 to operate (for example, turning on the pixel switch), thereby allowing the sensing signals (such as but not limited to impedance changes) sensed by the sensing unit 5 to be transmitted to the signal reader 12 for reading through the reading line 14. The signal reader 12 may transmit the read signal content to the processing chip 13 for processing, but it is not limited thereto.

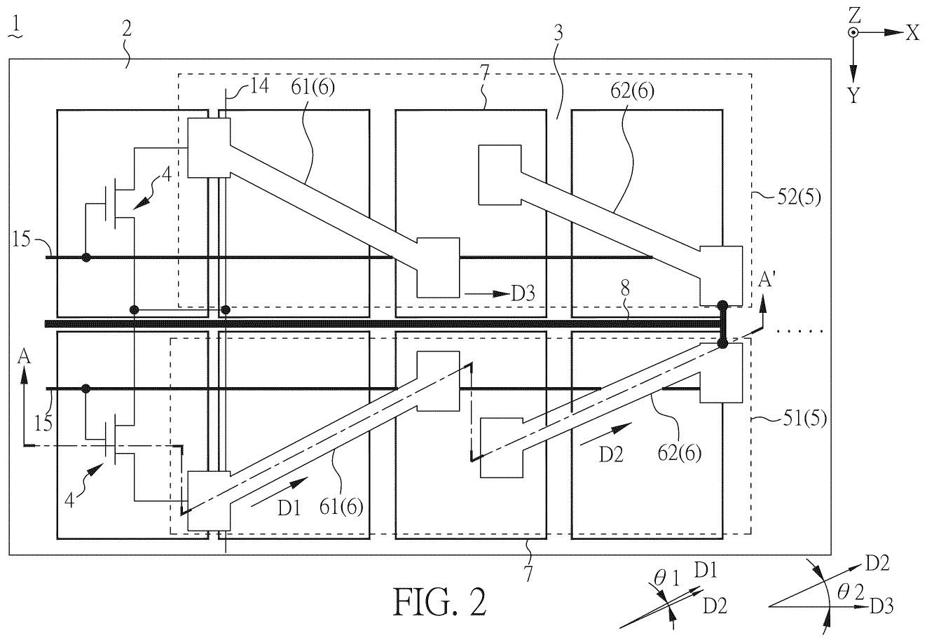

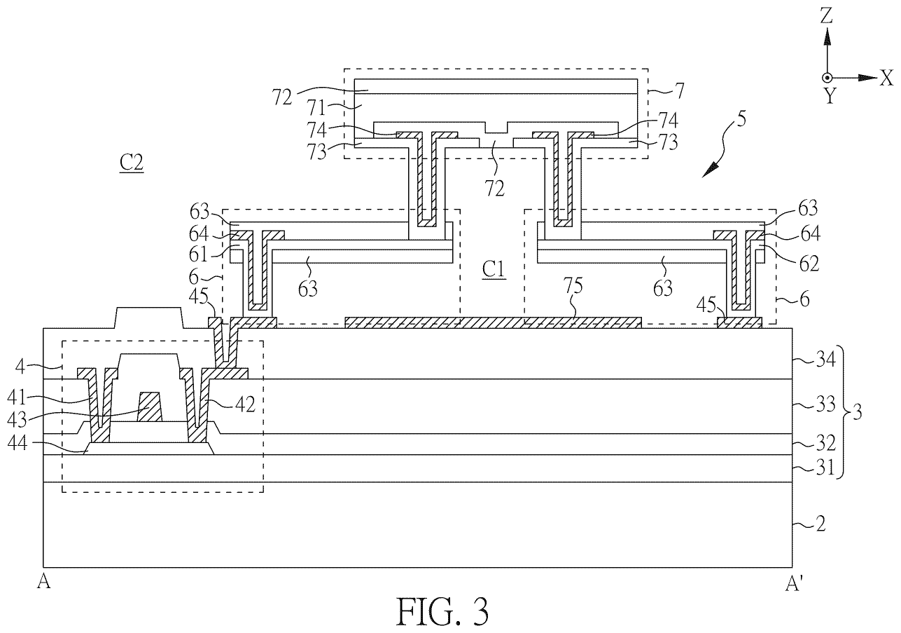

Next, please refer to FIG. 2 and FIG. 3, as well as FIG. 1 as an auxiliary reference. FIG. 2 is a schematic diagram of the driving circuit 4 and the sensing unit 5 according to the first embodiment of the present disclosure. FIG. 3 is a cross-sectional view of the driving circuit 4 and the sensing unit 5 of FIG. 2 taken along line A-A′. FIG. 2 and FIG. 3 illustrate the detailed structural features of the sensing unit 5. It is noted that, for clear illustration, FIG. 2 only shows the sensing unit 51 and another sensing unit 52, but the sensing device 1 may be provided with more sensing units 5 in actual application.

As shown in FIG. 2 and FIG. 3, the sensing device 1 includes a substrate 2, a circuit layer 3 and a plurality of sensing units 5. The circuit layer 3 is disposed on the substrate 2, and includes a plurality of driving circuits 4. Each sensing unit 5 includes a supporting part 6 and a sensing part 7. The supporting part 6 is electrically connected to one of the driving circuits 4. In the same sensing unit 5 (such as the sensing unit 51 or the sensing unit 52 in FIG. 2), the sensing part 7 is electrically connected to the supporting part 6 and, through the supporting part 6, the sensing part 7 is separated from the circuit layer 3 by a first cavity C1. For example, in the normal direction (Z) of the substrate 2, part of the first cavity C1 is disposed between the sensing part 7 and the circuit layer 3, and another part of the first cavity C1 is disposed between the supporting part 6 and the circuit layer 3. In addition, in the normal direction (Z) of the substrate 2, at least part of the supporting part 6 overlaps with the sensing part 7, that is, the two at least partially overlap, but it is not limited thereto. In addition, the sensing part 7 may be electrically connected to the driving circuit 4 through part of the supporting part 6, and the sensing part 7 may be electrically connected to a bias line 8 through another part of the supporting part 6, while it is not limited thereto. In addition, in the normal direction (Z) of the substrate 2, the supporting part 6 is closer to the substrate 2 than the sensing part 7, but it is not limited thereto.

In one embodiment, in the normal direction (Z) of the substrate 2, the supporting part 6 of each sensing unit 5 may at least partially overlap with one or more sensing parts 7 of different sensing units 5. In other words, the supporting part 6 of each sensing unit 5 may at least partially overlap with the sensing part 7 of another sensing unit 5. In addition, since the supporting part 6 may at least partially overlap with a plurality of sensing parts 7, the supporting part 6 of each sensing unit 5 may be disposed between the sensing part 7 of another sensing unit and the substrate 2.

In one embodiment, the supporting part 6 may include a first supporting member 61 and a second supporting member 62. The first supporting member 61 and the second supporting member 62 are detachable, but it is not limited thereto. In the normal direction (Z) of the substrate 2, the first supporting member 61 of one sensing unit 5 may at least partially overlap with the sensing part 7 of the sensing unit 5, and may at least partially overlap with one or more sensing parts 7 of other sensing units 5, while the second supporting member 61 of the sensing unit 5 may at least partially overlap with the sensing part 7 of the sensing unit 5, and may at least partially overlap with one or more sensing parts 7 of other sensing units 5. In addition, the first supporting member 61 of each sensing unit 5 may be electrically connected to one of the driving circuits 4, and the second supporting member 62 may be electrically connected to a bias line 8 of the sensing device 1, so that the sensing part 7 may be electrically connected to the driving circuit 4 through the first supporting member 61, and may be electrically connected to the bias line 8 through the second supporting member 62. By taking the sensing unit 51 of FIG. 2 as an example, one end of the first supporting member 61 of the sensing unit 51 may be electrically connected to the driving circuit 4, the other end of the first supporting member 61 may be electrically connected to the sensing part 7 of the sensing unit 51, one end of the second supporting member 62 of the sensing unit 51 may be electrically connected to the sensing part 7 of the sensing unit 51, and the other end of the second supporting member 62 may be electrically connected to the bias line 8, while it is not limited thereto. In addition, the driving circuit 4 and the sensing part 7 electrically connected to the first supporting member 61 may be disposed in different areas. Therefore, in one embodiment, in the normal direction (Z) of the substrate 2, the sensing part 7 of the sensing unit 51 and one of the driving circuits 4 of the sensing device 1 may not overlap.

In addition, in the sensing unit 51 shown in FIG. 2, in one embodiment, the first supporting member 61 extends along a first extension direction D1, and the second support member 62 extends along a second extension direction D2, wherein there may be a first included angle θ1 between the first extension direction D1 and the second extension direction D2. In one embodiment, the first included angle θ1 may be between 0 degrees and 20 degrees (that is, 0 degrees≤θ1≤20 degrees), while it is not limited thereto. In one embodiment, the first included angle θ1 may be between 0 degrees and 15 degrees (that is, 0 degrees≤01≤15 degrees), while it is not limited thereto. In one embodiment, the first included angle θ1 may be between 0 degrees and 10 degrees (that is, 0 degrees≤01≤10 degrees), while is not limited thereto. In one embodiment, the first extension direction D1 may be parallel to the second extension direction D2, while it is not limited thereto. When the first included angle θ1 between the first extension direction D1 and the second extension direction D2 falls within the aforementioned range, the first supporting member 61 and the second supporting member 62 may provide a relatively uniform supporting force for the sensing part 7, and the sensing part 7 is less likely to tilt due to uneven supporting force, wherein the sensing part 7 may be subject to contact the circuit layer 3 to cause heat dissipation if the degree of tilt is too large.

In one embodiment, the bias line 8 extends along a third extension direction D3. In one embodiment, the third extension direction D3 may be parallel to the extension direction of the scan line 15, but it is not limited thereto. In one embodiment, the third extension direction D3 may be parallel to the second extension direction D2, but it is not limited thereto. In one embodiment, there is a second included angle θ2 between the second extension direction D2 of the second supporting member 62 and the third extension direction D3. In one embodiment, the second included angle θ2 may be between 0 degrees and 20 degrees (that is, 0 degrees≤θ2≤20 degrees), while it is not limited thereto. In one embodiment, the second included angle θ2 may be between 5 degrees and 20 degrees (that is, 5 degrees≤θ1≤20 degrees), while it is not limited thereto. In one embodiment, the second included angle θ2 may be between 10 degrees and 20 degrees (that is, 10 degrees≤θ2≤20 degrees), while it is not limited thereto. When the second angle θ2 between the third extension direction D3 and the second extension direction D2 falls within the aforementioned range, the layout area of components can be saved, which is thus suitable for high-resolution sensing.

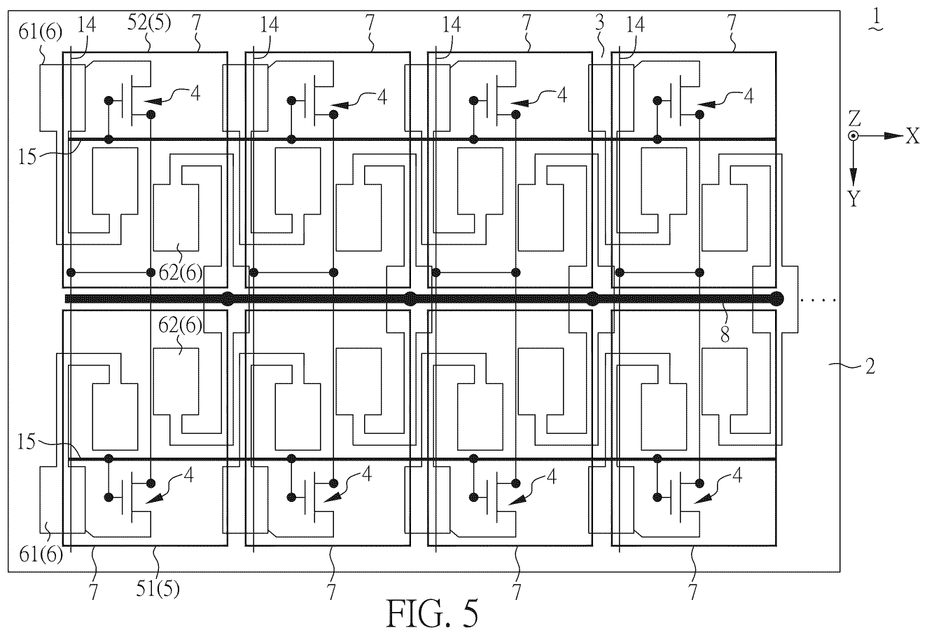

In one embodiment, the bias line 8 may be disposed on the substrate 2, but it is not limited thereto. In one embodiment, a plurality of sensing units 5 are provided on the substrate 2, and the supporting part 6 of one of the sensing units 5 and the supporting part 6 of another one of the sensing units 5 are designed to be mirrors with the bias line 8. By taking FIG. 2 as an example, when viewed from the normal direction (Z) of the substrate 2, the sensing unit 51 and another sensing unit 52 are respectively disposed on opposite sides of the bias line 8, wherein the supporting part 6 of the sensing unit 51 and the supporting part 6 of another sensing unit 52 are designed to be mirrors with the bias line 8, but it is not limited thereto. In addition, in one embodiment, one end of the second supporting member 62 of the sensing unit 51 that is electrically connected to the bias line 8 and one end of the second supporting member 62 of the sensing unit 52 that is electrically connected to the bias line 8 may be shared (for example, connected to each other, as shown in the example of FIG. 5), or may be not shared (for example, separated from each other, as shown in the example of FIG. 2), while it is not limited thereto.

Next, the arrangement relationship and details of each component in the normal direction (Z) of the substrate 2 will be described.

As shown in FIG. 3, in one embodiment, the circuit layer 3 is disposed on the substrate 2, and the sensing unit 5 is disposed on the circuit layer 3.

In one embodiment, the circuit layer 3 may include a first insulating layer 31, a second insulating layer 32, a third insulating layer 33, a fourth insulating layer 34 and a driving circuit 4, while it is not limited thereto. The first insulating layer 31 may be disposed on the substrate 2. The second insulating layer 32 may be disposed on the first insulating layer 31. The third insulating layer 33 may be disposed on the second insulating layer 32. The fourth insulating layer 34 may be disposed on the third insulating layer 33. The driving circuit 4 may include a drain/source electrode 41, a source/drain electrode 42, a gate electrode 43 and a semiconductor layer 44, while it is not limited thereto. The driving circuit 4 may be disposed on the first insulating layer 31, while it is not limited thereto. In addition, the source/drain electrode 42 may be electrically connected to the first supporting member 61 of the supporting part 6 through a conductive connecting member 45.

In one embodiment, the supporting part 6 of the sensing unit 5 may be disposed on the fourth insulating layer 34. A fifth insulating layer 63 may be provided around the first supporting member 61 of the supporting part 6, and the first supporting member 61 may be, for example but not limited to, fixed to a connecting member 45 on the fourth insulating layer 34 through a first fixing member 64. Another fifth insulating layer 63 may be provided around the second supporting member 62, and the second supporting member 62 may be, for example but not limited to, fixed to another connecting member 45 on the fourth insulating layer 34 through another first fixing member 64 and electrically connected to the bias line 8 through another connecting member 45 (please refer to FIG. 2), wherein “fixing” here may include locking, pasting or welding, while it is not limited thereto.

In one embodiment, the sensing part 7 of the sensing unit 5 may include a sensing layer 71, a sixth insulating layer 72, at least one absorbing component 73 and at least one second fixing member 74. For example, in the example of FIG. 3, the sensing part 7 may include two absorbing components 73 and two second fixing members 74, while it is not limited thereto. The sensing layer 71 is disposed on the absorbing component 73. The sixth insulating layer 72 may be disposed on the sensing layer 71. One of the absorbing components 73 is fixed to the first supporting member 61 through one of the second fixing members 74, and the other one of the absorbing components 73 is fixed to the second supporting part 62 through the other one of the second fixing members 74. In addition, in one embodiment, a reflective layer 75 may be disposed on the fourth insulating layer 34, and the reflective layer 75 may be disposed between the sensing layer 71 and the fourth insulating layer 34.

In addition, in one embodiment, the sensing device 1 may be, for example, an infrared sensing device, such as a long wavelength infrared (LWIR) sensing device or a medium wavelength infrared (MWIR) sensing device, short wavelength infrared (SWIR) sensing devices, etc., while it is not limited thereto. In one embodiment, the sensing layer 71 may be, for example, a thermistor, but it is not limited thereto. In one embodiment, when light passes through the sensing part 7, the absorbing component 73 may absorb the light and convert light energy into heat energy, and the sensing layer 71 may produce impedance changes through temperature changes, thereby generating a sensing signal, but it is not limited thereto. In addition, in one embodiment, when light passes through the sensing part 7, part of the light may not be absorbed by the absorbing component 73 and thus enter the first cavity C1. At this moment, the reflective layer 75 may reflect the part of the light for reuse. For example, the absorbing component 73 may absorb the light reflected by the reflective layer 75, but it is not limited thereto.

Next, the materials of the components in the circuit layer 3 will be described. In one embodiment, the first insulating layer 31 may be, for example, a buffer layer, but it is not limited thereto. In one embodiment, the second insulating layer 32 may be, for example, a gate insulating layer (GI layer), but it is not limited thereto. In one embodiment, the material of the first insulating layer 31 or the second insulating layer 32 may be, for example, organic material or inorganic material, wherein the organic material may include epoxy resin, silicone resin, acrylic resin or other suitable materials, or a combination thereof, while it is not limited thereto, and the inorganic material may include silicon nitride, silicon oxide, silicon oxynitride, silicon carbide, aluminum oxide, hafnium oxide or other suitable materials, or a combination thereof, while it is not limited thereto. In one embodiment, the third insulating layer 33 may be, for example, a dielectric layer, and may include various organic materials or inorganic materials. The types of organic materials or inorganic materials here may be as described in the previous paragraphs, while it is not limited thereto. In one embodiment, the material of the fourth insulating layer 34 may include silicon oxide, silicon nitride, silicon oxynitride or other suitable materials, or a combination thereof, while it is not limited thereto. In one embodiment, the material of the semiconductor layer 44 may include amorphous silicon, polycrystalline silicon, oxide semiconductor or other suitable materials, or a combination thereof, wherein the component of the oxide semiconductor may include a metal oxide, and the metal may be indium, gallium, zinc or tin, or a combination thereof, while it is not limited thereto. In one embodiment, the oxide semiconductor may include indium gallium zinc oxide (IGZO), while it is not limited thereto.

The materials of the components in the sensing unit 5 are described here. In one embodiment, the fifth insulating layer 63 or the sixth insulating layer 72 may be, for example, a protective layer for protecting the first supporting member 61, the second supporting member 62 or the sensing layer 71. In one embodiment, the material of the fifth insulating layer 63 or the sixth insulating layer 72 may include organic material, inorganic material, other suitable protective materials, or a combination thereof, but it is is not limited thereto. The types of organic materials or inorganic materials here may be as described in the previous paragraphs. In one embodiment, the material of the first supporting member 61 or the second supporting member 62 may include titanium, aluminum, titanium nitride, titanium aluminide, titanium aluminum nitride, titanium aluminum oxide, titanium silicon aluminum, titanium tungsten, titanium tungsten nitride, aluminum nitride or other suitable materials, or a combination thereof, while it is not limited thereto. In one embodiment, the material of the first fixing member 64 or the second fixing member 74 may include molybdenum, molybdenum nitride, tungsten, molybdenum tungsten, or other suitable materials, or a combination thereof, while it is not limited thereto. In one embodiment, the material of the absorbing component 73 may include titanium, titanium nitride, platinum, gold, nickel, niobium or other suitable materials, or a combination thereof, while it is not limited thereto. In one embodiment, the material of the sensing layer 71 may include amorphous silicon, vanadium oxide, yttrium barium copper oxide, germanium silicon oxide (GeSiO), silicon germanium, bismuth lanthanum strontium manganese oxide (BiLaSrMnO) or other suitable materials or a combination thereof, while it is not limited thereto.

In addition, in one embodiment, at the early stage of the process of the sensing device 1, a sacrificial (SAC) layer may be disposed between the fourth insulating layer 34 and the sensing layer 71 or on the fourth insulating layer 34. The sacrificial layer may be removed, for example, by etching at a later stage of the process or when the process is completed, thereby generating a first cavity C1 and/or a second cavity C2, but it is not limited thereto. In one embodiment, the material of the sacrificial layer may include polyimide, acrylic resin, photoresist (such as SU-8), poly-α-xylylene or other suitable materials, or a combination thereof, while it is not limited thereto.

As a result, in the normal direction (Z) of the substrate 2, the supporting part 6 may be disposed below the sensing layer 71, so as to reduce the interaction between the length of the supporting part 6 and the sensing area, thereby increasing the sensing. Alternatively, because the length of the supporting part 6 is increased, better thermal insulation may be provided.

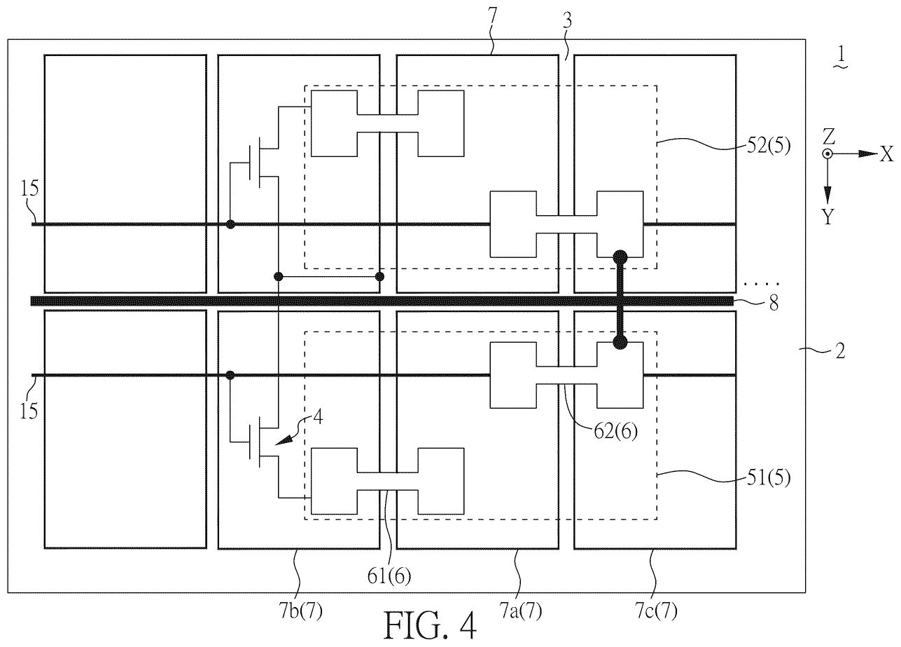

The sensing unit 5 of the present disclosure may have different implementation aspects. FIG. 4 is a schematic diagram of the driving circuit 4 and the sensing unit 5 according to the second embodiment of the present disclosure, and please refer to FIG. 1 to FIG. 3 at the same time. It is noted that, for clear illustration, FIG. 4 only shows the sensing unit 51, the sensing unit 52 and the two driving circuits 4, but the sensing device 1 may have more sensing units 5 and driving circuits 4 in actual application.

Some features of the embodiment of FIG. 4 may be known from the description of the embodiment of FIG. 2, and thus the following description mainly focuses on the differences.

In one embodiment, the first extension direction D1 may be parallel to the second extension direction D2, while it is not limited thereto. As shown in FIG. 4, the first extension direction D1 of the first supporting member 61 is parallel to the second extension direction D2 of the second supporting member 62, and the second extension direction D2 of the second supporting member 62 is parallel to the third extension direction D2 of the bias line 8. That is, the first extension direction D1, the second extension direction D2 and the third extension direction D3 are parallel to each other.

In addition, in one embodiment, in the normal direction (Z) of the substrate 2, the first supporting member 61 at least partially overlaps with at least two adjacent sensing parts 7; for example, the first supporting member 61 of the sensing unit 51 may at least partially overlap with the sensing part 7 (for example, the sensing part 7a) of the sensing unit 51, and may at least partially overlap with another sensing part 7 (for example, the sensing part 7b) adjacent to the sensing part 7 of the sensing unit 51, while it is not limited thereto. In one embodiment, in the normal direction (Z) of the substrate 2, the second supporting member 62 partially overlaps with at least two adjacent sensing parts 7. For example, the second supporting member 62 of the sensing unit 51 may at least partially overlap with the sensing part 7 (for example, the sensing part 7c) of the sensing unit 51, and may at least partially overlap with still another sensing part 7 adjacent to the sensing part 7 of the sensing unit 51, while it is not limited thereto.

In addition, in the embodiment of FIG. 4, the supporting part 6 of one of the sensing units 5 and the supporting part 6 of another one of the sensing units 5 are designed to be mirrors with the bias line 8. For example, in the normal direction (Z) of the substrate 2, the supporting part 6 of the sensing unit 51 and the supporting part 6 of another sensing unit 52 are designed to be mirrors with the bias line 8, but it is not limited thereto.

As a result, the fourth embodiment can be understood.

The sensing unit 5 of the present disclosure may have different implementation aspects. FIG. 5 is a schematic diagram of the driving circuit 4 and the sensing unit 5 according to the third embodiment of the present disclosure, and please refer to FIG. 1 to FIG. 4 at the same time.

Some features of the embodiment of FIG. 5 may be known from the description of the embodiment of FIG. 2, and thus the following description mainly focuses on the differences.

In the embodiment of FIG. 5, in the normal direction (Z) of the substrate 2, the first supporting member 61 and the second supporting member 62 of each sensing unit 5 at least partially overlap with the sensing part 7 of the sensing unit 5. By taking the sensing unit 51 as an example, in the normal direction (Z) of the substrate 2, both the first supporting member 61 and the second supporting member 62 of the sensing unit 51 at least partially overlap with the sensing part 7 of the sensing unit 51, and one end of the first supporting member 61 may be electrically connected to the driving circuit 4 overlapping with the sensing part 7 of the sensing unit 51, and the other end of the first supporting member 61 may be electrically connected to the sensing part 7 of the sensing unit 51. One end of the second supporting member 62 may be electrically connected to the sensing part 7 of the sensing unit 51, and the other end of the second supporting member 62 may be electrically connected to the bias line 8. However, the present disclosure is not limited thereto. The third embodiment is different from the first embodiment in that, in the normal direction (Z) of the substrate 2, the sensing part 7 of the sensing unit 5 of the third embodiment overlaps with the driving circuit 4 electrically connected to the sensing unit 5.

In addition, in one embodiment, the supporting part 6 of one of the sensing units 5 and the supporting part 6 of another one of the sensing units 5 are designed to be mirrors with the bias line 8. For example, in the normal direction (Z) of the substrate 2, the supporting part 6 of the sensing unit 51 and the supporting part 6 of another sensing unit 52 are designed to be mirrors with the bias line 8. However, the present disclosure is not limited thereto.

As a result, the third embodiment can be understood.

In one embodiment, based on at least comparing the present disclosure with a product through mechanism observation, such as the presence or absence of components or the operational relationship between components, it is able to provide the evidence for determining whether the product falls within the patent protection scope of the present disclosure, but not limited thereto. In one embodiment, the mechanism observation may be achieved, for example, by using equipment such as an optical microscope or a scanning microscope, but not limited thereto.

As a result, with the sensing device of the present disclosure, it is able to increase the sensing area, or increase the length of the supporting member, thereby providing better thermal insulation.

Details or features of various embodiments of the present disclosure may be mixed and matched as long as they do not violate the spirit of the disclosure or conflict with each other.

The aforementioned specific embodiments should be construed as merely illustrative, and not limiting the rest of the present disclosure in any way.

1. A sensing device, comprising:
a substrate;
a circuit layer disposed on the substrate, and provided with a plurality of driving circuits; and
a plurality of sensing units disposed on the circuit layer, each sensing unit including:
a supporting part electrically connected to one of the driving circuits; and
a sensing part electrically connected to the supporting part, and separated from the circuit layer by a first cavity through the supporting part,
wherein at least part of the supporting part overlaps with the sensing part in a normal direction of the substrate.

2. The sensing device as claimed in claim 1, wherein the supporting part at least partially overlaps with the sensing part of another sensing unit in a normal direction of the substrate.

3. The sensing device as claimed in claim 2, wherein the supporting part is disposed between the substrate and the sensing part of the another sensing unit.

4. The sensing device as claimed in claim 1, wherein the sensing part does not overlap with the one of the driving circuits in a normal direction of the substrate.

5. The sensing device as claimed in claim 1, further comprising a bias line disposed on the substrate, wherein the supporting part includes a first supporting member and a second supporting member, the first supporting member is electrically connected to the one of the driving circuits, and the second supporting member is electrically connected to the bias line.

6. The sensing device as claimed in claim 5, wherein an included angle between an extension direction of the first supporting member and an extension direction of the second supporting member is between 0 and 10 degrees.

7. The sensing device as claimed in claim 5, wherein an included angle between an extension direction of the second supporting member and an extension direction of the bias line is between 0 and 20 degrees.

8. The sensing device as claimed in claim 7, wherein an included angle between the extension direction of the second supporting member and an extension direction of the bias line is between 10 and 20 degrees.

9. The sensing device as claimed in claim 5, wherein an extension direction of the first supporting member is parallel to an extension direction of the second supporting member.

10. The sensing device as claimed in claim 5, wherein an extension direction of the second supporting member is parallel to an extension direction of the bias line.

11. The sensing device as claimed in claim 1, further comprising a bias line disposed on the substrate, wherein the supporting part of one of the sensing units and the supporting part of another one of the sensing units are designed to be mirrors with the bias line.

12. The sensing device as claimed in claim 5, wherein the first supporting member 61 of the sensing unit at least partially overlaps with the sensing part of the sensing unit and at least partially overlaps with the sensing part of another sensing unit, and the second supporting member of the sensing unit at least partially overlaps with the sensing part of the sensing unit and at least partially overlaps with the sensing part of another sensing unit.

13. The sensing device as claimed in claim 12, wherein one end of the second supporting member of the sensing unit that is electrically connected to the bias line and one end of the second supporting member of another sensing unit that is electrically connected to the bias line are connected to each other.

14. The sensing device as claimed in claim 12, wherein one end of the second supporting member of the sensing unit that is electrically connected to the bias line and one end of the second supporting member of another sensing unit that is electrically connected to the bias line are separated from each other.

15. The sensing device as claimed in claim 5, wherein the circuit layer further includes a first insulating layer, a second insulating layer, a third insulating layer and a fourth insulating layer, the first insulating layer is disposed on the substrate, the second insulating layer is disposed on the first insulating layer, the third insulating layer is disposed on the second insulating layer, and the fourth insulating layer is disposed on the third insulating layer.

16. The sensing device as claimed in claim 15, wherein one of the driving circuits includes a drain/source electrode, a source/drain electrode, a gate electrode and a semiconductor layer, the one of the driving circuits is disposed on the first insulating layer, and the source/drain electrode of the one of the driving circuits passes is electrically connected to the first supporting member of the supporting part through a conductive connecting member.

17. The sensing device as claimed in claim 16, wherein a fifth insulating layer is provided around the first supporting member of the supporting part, and the first supporting member is fixed to the connecting member on the fourth insulating layer through a first fixing member, and wherein another fifth insulating layer is provided around the second supporting member, and the second supporting member is fixed to another connecting member on the fourth insulating layer and electrically connected to the bias line through another first fixing member.

18. The sensing device as claimed in claim 17, wherein the sensing part of the sensing unit includes a sensing layer, a sixth insulating layer, at least one absorbing component and at least one second fixing member, the sensing layer is disposed on the at least one absorbing component, the sixth insulating layer is disposed on the sensing layer, one of the at least one absorbing component is fixed to the first supporting member through one of the at least one second fixing member, and another one of the at least one absorbing component is fixed to the second supporting member through the another one of the at least one second fixing member.

19. The sensing device as claimed in claim 15, wherein the fourth insulating layer is provided with a reflective layer disposed between the sensing layer and the fourth insulating layer.

20. The sensing device as claimed in claim 5, wherein the first supporting member and the second supporting member of each sensing unit at least partially overlap with the sensing part of the sensing unit and, in the normal direction of the substrate, the sensing part of the sensing unit overlaps with the driving circuit electrically connected to the sensing unit.
